(19) United States
(12) Patent Application Publication
(10) Pub. No.: US 2014/0151731 A1
(43) Pub. Date: Jun. 5, 2014

(54) PHOTON CONVERSION STRUCTURES, DEVICES FOR LIGHT EMITTING DEVICES

(71) Applicant: Nguyen The Tran, Garden Grove, CA (US)

(72) Inventor: Nguyen The Tran, Garden Grove, CA (US)

(21) Appl. No.: 13/918,911

(22) Filed: Jun. 15, 2013

Related U.S. Application Data
(60) Provisional application No. 61/659,993, filed on Jun. 15, 2012.
(60) Provisional application No. 61/659,995, filed on Jun. 15, 2012.

(51) Int. Cl. H01L 33/56

(52) U.S. Cl. CPC H01L 33/56
USPC 257/98; 438/26

(57) ABSTRACT

The disclosure herein provides photon conversion, extraction and distribution structures, devices, and methods for light emitting devices. The structures, devices, and methods described herein can improve the efficiency and/or light distribution of light emitting devices.

### CROSS-REFERENCE TO RELATED APPLICATIONS

This application claims the priority filling date of provisional applications filed in the United States of America with application numbers as follows: U.S. 61/659,995 filed on Jun. 15th, 2012; and U.S. 61/659,993 filed on Jun. 15th, 2012.

### BACKGROUND

1. Field

This disclosure relates generally to the field of light emitting devices, and more specifically to photon conversion structures, deices, and methods for light emitting diodes.

2. Description

With the development of technologies in light emitting device, single and/or multiple light emitting chips or light sources, such as light emitting diode (LED) chips, can be used in light devices for light fixtures, backlighting for displays, or the like. Generally, in light emitting devices, some generated light can be trapped inside the device, resulting in low efficiency and lifetime. Further, the distribution of generated light to the exterior of the device can be inefficient and/or otherwise unsatisfactory, for example in terms of uneven color distribution. Accordingly, it can be advantageous to provide structures, devices, and methods to improve the efficiency and/or distribution of light emitting devices.

### SUMMARY

Advancements in light emitting device technologies make it possible to improve the efficiency and/or light distribution of light emitting devices via one or more guiding structures, deices, and methods.

One aspect of the invention provides a light emitting device, which comprises: an LED light source and a photon conversion, extraction and distribution (PCED) structure placed over the LED light source. The LED light source comprises a light emitting diode (LED) and an encapsulation encapsulating the LED, the LED being configured to emit light beams of a first color, the encapsulation comprising at least one phosphor material configured to absorb light beams of the first color from the LED and emit light beams of a second color. The PCED structure placed over the LED encapsulation, the PCED structure comprising a body defined by a bottom, a top and a side, the light guide structure body being configured to receive via the bottom and direct to the top light beams from the LED encapsulation. The top and side of a PCED structure are configured in a manner that some reflected light undergoing total internal reflection mechanism at side surfaces can be transmitted through top surfaces, or in a manner that reflected light undergoing total internal reflection mechanism at top surfaces can be transmitted through side surfaces.

The PCED structure is configured in a manner that the ratio of its height to its width is maintained as large as possible to improve the efficiency. The height of PCED structure can be minimized to reduce the absorption loss, bulkiness, and material cost by reducing the width of a PCED structure.

The top of a PCED structure can comprise of different structures. In some embodiments, the top surface of a PCED structure can be a transparent flat top surface and form an acute angle with transparent side surfaces. In some embodiments, the top surface of a PCED structure can be a transparent flat top surface and form an obtuse angle with transparent side surfaces. In some embodiments, the top surface of a PCED structure comprises substructures of different shapes such as conical/pyramidal structure between two adjacent polygonal/cubical structures. In some embodiments, the top surface of a PCED structure has curved shapes/segments.

In some embodiments, top and side surfaces of a PCED structure are configured in a manner that reflected light at a top surface is refracted at the side surface or that reflected light at a side surface is refracted at a top surface to improve light extraction efficiency or light spreading.

In some embodiments, PCED structure is made of one type of material mixture through its entire structure.

In some embodiments, PCED structure consists of multiple layers that are made of different materials.

### BRIEF DESCRIPTION OF THE DRAWINGS

FIGS. 1A-1B illustrate examples of embodiments of light emitting devices comprising a hemispherical cover.

FIG. 2 illustrates light emitting patterns of examples of embodiments of light emitting devices.

FIG. 3A illustrates a perspective view of an example of an embodiment of a light emitting device comprising an embodiment of a PCED structure before being attached to light emitting package.

FIG. 3B illustrates a perspective view of an example of an embodiment of a light emitting device comprising an embodiment of a PCED structure.

FIG. 4 illustrates a perspective view of an example of an embodiment of a PCED structure.

FIGS. 5A-5B illustrate a cross-section along a long axis and a short axis of an example of embodiments of PCED structures.

FIGS. 6A-6B illustrate a cross-section in examples of embodiments of PCED structures with multiple layers.

FIG. 7 illustrates light travel patterns in examples of embodiments of PCED structures.

FIG. 8 illustrates a cross-section of an example of an embodiment of a PCED structure comprising a top with two types of sub-structures along a long dimension of the PCED structure.

FIG. 9 illustrates a cross-section of an example of an embodiment of a PCED structure comprising a top of continuous surface along a long dimension of the PCED structure.

FIG. 10 illustrates a perspective view of an example of an embodiment of a PCED structure comprising a flat top of the PCED structure.

### DETAILED DESCRIPTION

Embodiments of the invention will now be described with reference to the accompanying figures. The terminology used in the description presented herein is not intended to be interpreted in any limited or restrictive manner, simply because it is being utilized in conjunction with a detailed description of certain specific embodiments of the invention. Furthermore, embodiments of the invention may comprise several novel features, no single one of which is solely responsible for its desirable attributes or which is essential to practicing the inventions herein described.

The disclosure herein provides photon enhancement conversion structures, devices, and methods for light emitting devices. The structures, devices, and methods described herein can improve the efficiency and/or light distribution of light emitting devices.

Light emitting devices can comprise one or more light sources. For example, light emitting devices can comprise one or more light emitting diode (LED) chips, fluorescent, incandescent, solar, or any other light generating source or chip that is currently available or to be developed in the future. Further, light emitting devices can comprise one or more phosphors or other materials that are configured to absorb and/or reemit light. Although some embodiments are described herein in relation to light emitting devices comprising an LED light source and/or LED chips, it should be understood to one of ordinary skill in the art that the underlying concepts disclosed herein can be applied to light emitting devices comprising any other type of light source.

Generally, for any type of light emitting device that comprises a light source, some generated light can be trapped inside the light emitting device, resulting in low efficiency and lifetime. Further, in certain light emitting devices, the color and intensity distribution of generated light to the exterior of the light emitting device can be inefficient and/or otherwise unsatisfactory. For example, there can be uneven distribution of one or more colors or density of light in certain directions and/or areas. Accordingly, it can be advantageous to provide photon conversion enhancement structures, devices, and/or methods that can improve the efficiency and/or distribution of light emitted from a light emitting device.

### Hemispherical Cover

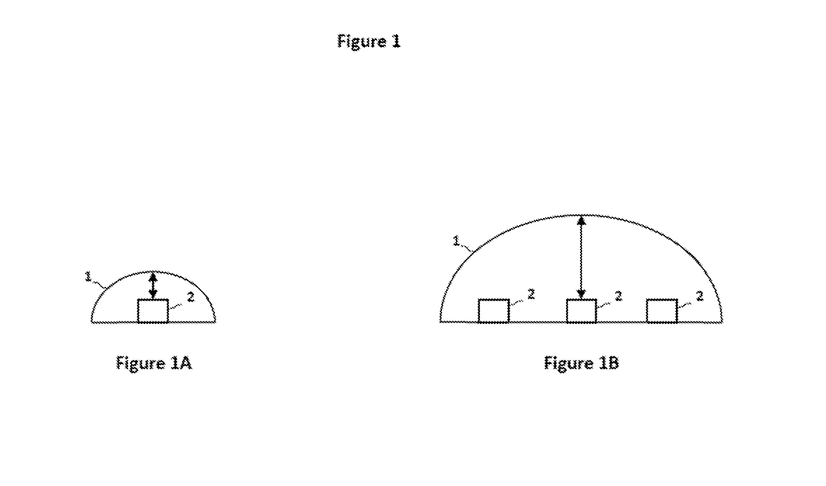

In some embodiments, a light emitting device can comprise a convex, hemispherical lens configured to control and/or improve the distribution of light and/or efficiency. FIG. 1A illustrates a convex, hemispherical lens 1 configured to be placed over a light source 2 of a light emitting device.

As illustrated in FIG. 1A, in some embodiments, a light emitting device can comprise only one light source 2. In some embodiments, a convex, hemispherical lens 1 can be configured to be placed over the single light source 2. By placing a convex, hemispherical lens 1 over the light source 2, the distribution of light generated by the light source 2 can be controlled to a certain degree. For example, some of the generated light can be guided to exit the hemispherical cover 1 in directions that are substantially perpendicular to tangential lines at each point along the hemispherical curvature.

However, such convex, hemispherical covers 1 can be costly and inefficient. For example, some light generated by the single light source 2 or a portion thereof can be trapped in the interior space underneath the cover 1, thereby wasting at least some of the lighting capacity of the light source 2. Further, light that is trapped inside the cover 1 can further lead to heating of the interior space. The heat and/or light trapped under the cover can also add stress to the lens 1.

Furthermore, such disadvantages of convex, hemispherical covers 1 are generally multiplied for lighting devices that comprise a plurality of light sources 2. As illustrated in FIG. 1B, in order to accommodate a plurality of light sources 2, the height of a hemispherical cover 1 generally must be increased. Accordingly, there can be additional space underneath the cover 1 compared to lighting devices with only one light source 2. Due to the additional space, a larger amount of generated light can be trapped and absorbed underneath the cover 1, thereby resulting in even lower efficiency and lifetime compared to lighting devices with only one light source 2. As a result, even more heat can be generated, thereby adding to the stress exerted on the cover 1. Further, use of a hemispherical cover 1 in conjunction with a lighting device comprising a plurality of light sources 2 can also result in bulky packaging and can require highly transparent materials. For at least these reasons, it can be difficult, both economically and technically, to scale up a convex, hemispherical cover 1 for a light emitting device.

In contrast, certain embodiments of the photon conversion enhancement structures, devices, and methods for light emitting devices as described herein can provide light emitting devices with improved efficiency and/or light distribution compared to light emitting devices comprising hemispherical covers 1 while also providing a slimmer configuration or profile. As such, in certain embodiments, a light emitting device can comprise a plurality of light sources 2 while mitigating at least some of the problems discussed above related to hemispherical covers 1, including but not limited to generated light being trapped underneath the cover 1, excessive heating and/or stress on the cover 1, and distribution of light.

Generally, LEDs can emit a variety of colors of light, some of which can be combined to produce white light. One method of producing white LED (WLED) light is to use phosphor materials that absorb blue LED-emanated light and emit yellow or greenish yellow light. As such, one or more LED chips and one or more phosphor materials can be used in combination to produce white light for lighting, backlighting displays, and/or any other lighting purpose.

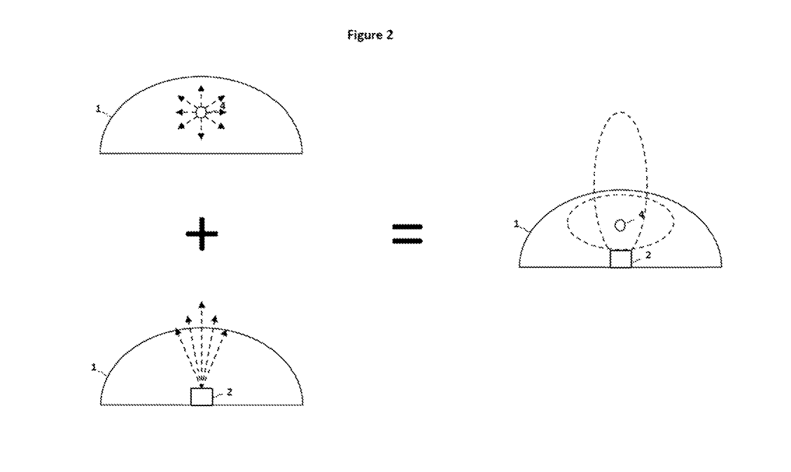

As illustrated in FIG. 2, an LED chip 2 generally emits light in a directional manner. In other words, light or colored light emitted by an LED generally travels in a substantially straight line from the LED chip 2. In contrast, a phosphor 4 generally emits light in an isotropic manner. In other words, light of colored light emitted by a phosphor 4 generally travels in all directions from the phosphor 4.

Accordingly, when light emitted from an LED chip 2 and a phosphor 4 are combined, an uneven distribution of light and/or colors is obtained as illustrated in FIG. 2. The light near the center of the LED chip 2 is denser as light emitted from both the LED chip 2 and phosphor 4 combines in that area. However, light near the sides or peripheral region of the LED chip 2 are not as dense, because only light emitted from the phosphor 4 reach the sides or peripheral region and not light emitted from the LED chip 2.

In other words, near the center of the LED chip 2, there is relatively more light emitted from the LED chip 2 than light emitted from the phosphor 4. Near the sides or peripheral regions of the LED chip 2, there can be relatively more light emitted from the phosphor 4 than light emitted from the LED chip 2. As such, a ratio of light emitted from the LED chip 2 to light emitted from the phosphor 4 is higher in the central region and lower in the sides or peripheral region. As a result, the color of light at different points can be different due to the different combinations of light emitted from the LED chip 2 and one or more phosphors 4.

In order to more evenly distribute light and/or color thereof, in some embodiments, a light emitting device can comprise PCED structures, devices, and methods configured to decentralize light and obtain a more even distribution of light. In certain embodiments, a portion of light near the center of the LED chip 2 can be reflected or otherwise manipulated to travel to the side or peripheral regions in order to obtain a more decentralized emission of light.

### Light Emitting Device Overview and Inner PCED Structure

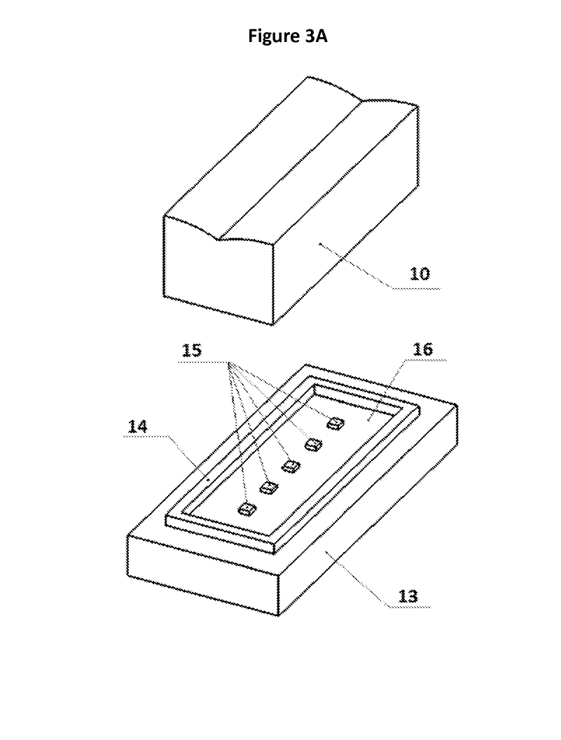

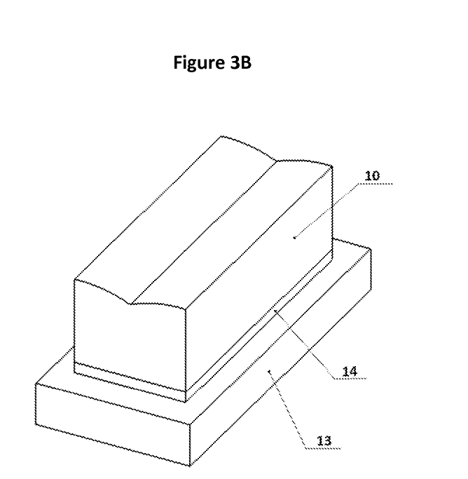

As discussed above, in some embodiments, a light emitting device can comprise one or more light sources and/or light or photon guiding structures. FIGS. 3A and 3B illustrate a perspective view of an example of an embodiment of a light emitting device with a top portion of PCED structure before being placed on top of an LED package and with an attached PCED structure, respectively. As illustrated in FIG. 3A, a light emitting device can comprise a lead-frame or chip-on-board substrate housing 13, at least one light generating chips 15, a PCED structure or top portion of a PCED structure 10, an encapsulation layer 16, and supporting structure 14. Gold wires for electrical connection and electric terminal are not shown.

In some embodiments, a light emitting device can comprise one or more light sources or light generating chips 15. For example, the one or more light sources can comprise one or more LED light sources or any other light generating sources or chips 15. The one or more LED chips 15 can be configured to emit light beams of a first color. In some embodiments, the one or more light emitting sources or LED chips 15 can be arranged in a line and/or two-dimensional array. The two-dimensional array of light emitting chips or LED chips 15 can comprise any row and/or column dimensions.

In some embodiments, the encapsulation layer 16 can made of transparent materials such as, but not limited to, silicone, glass, acrylic materials. In certain embodiments, the encapsulation layer 16 can contain one or more wavelength conversion materials such as green, yellow, orange, and/or red phosphor material. In other words, the LED encapsulation layer 16 can comprise at least one phosphor material configured to absorb light beams of the first color from the LED 16 and emit light beams of a second color. For example, in certain embodiments, blue light emanated from LED chips 16 can be partially absorbed by phosphor materials followed by emission of orange, red, and/or greenish-yellow light by one or more phosphor materials.

As used hereinafter, green, yellow, orange, and/or red phosphors or phosphor materials refer to wavelength conversion materials that are configured to emit light comprising wavelengths that are perceived as green, yellow, orange, and/or red respectively by normal eyes upon being activated by an appropriate wavelength.

In certain embodiments, a PCED structure 10 can be configured to be placed over the LED encapsulation 16. In certain embodiments, the PCED structure 10 can be made of transparent materials such as, but not limited to, silicone, PMMA, polycarbonate, and/or glass. In addition, in some embodiments, the PCED structure 10 can be made of material comprising certain surface texture and/or roughness in order to facilitate distribution of light. Moreover, in some embodiments, the PCED structure 10 can contain wavelength conversion materials such as green, yellow, orange, and/or red phosphor materials to improve light output and/or to adjust color quality. In certain embodiments, the light or PCED structure 10 can be made of material with a reflective index that is equal or lower than that of the encapsulation layer 16.

In some embodiments, a PCED structure 10 can be made of transparent materials and resides on top of the encapsulation layer 16 that contains wavelength conversion materials such as green, yellow, orange, and/or red phosphor materials that are mixed together. In some embodiments, the encapsulation layer 16 comprises two layers: a first layer contains red and/or orange phosphor materials and a second layer contains yellow and/or green phosphor materials. In some embodiments, the first layer resides below the second layer to absorb backward emitted light from the second layer. In some embodiments, the first layer resides on top of the second layer.

In some embodiments, a PCED structure 10 can be made of transparent materials containing wavelength conversion materials such as green, yellow, orange, and/or red phosphor materials, and resides on top of the encapsulation layer 16 that can be made of a transparent material.

In some embodiments, a PCED structure 10 can be made of a transparent material containing wavelength conversion materials such as green, and/or yellow phosphor materials, and resides on top of the encapsulation layer 16 that can be made of a transparent material containing wavelength conversion materials such as orange, and/or red phosphor materials. The wavelength conversion materials in the encapsulation layer 16 can absorb backscattered/backward-emitted light and convert to orange and/or red light.

In some embodiments, a PCED structure 10 can be made of a transparent material containing wavelength conversion materials such as orange, and/or red phosphor materials, and resides on top of the encapsulation layer 16 that can be made of a transparent material containing wavelength conversion materials such as green, and/or yellow phosphor materials.

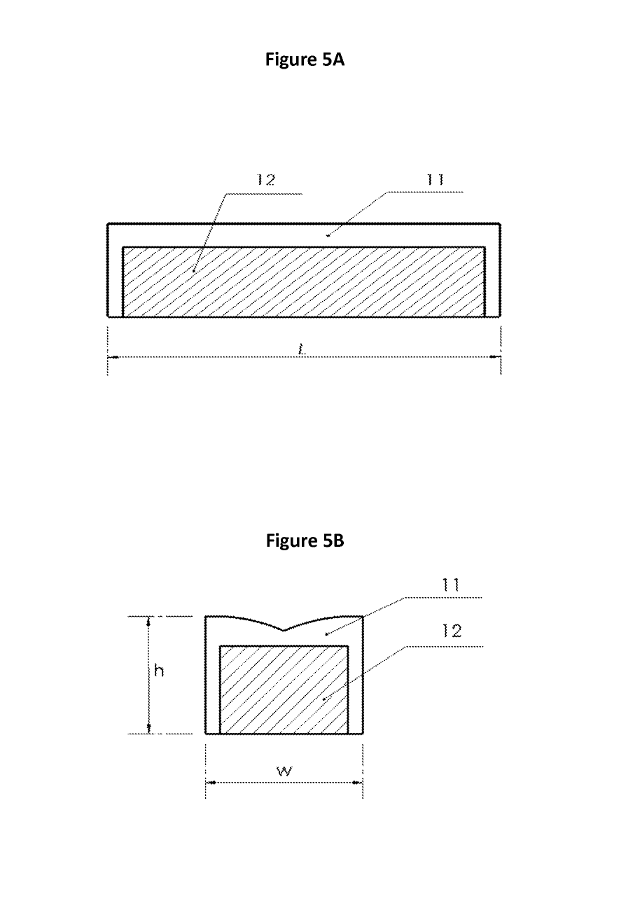

In some embodiments, a PCED structure 10 can consist of a clear layer/structure and a transparent layer containing wavelength conversion materials. FIGS. 5A-5B are cross-section of a PCED structure along a short axis and a long axis of the PCED structure, to illustrate one of embodiments of the invention. As shown in FIG. 5A or 5B, the layer 11 is made of a transparent materials and the layer 12 is made of a transparent material containing wavelength conversion materials.

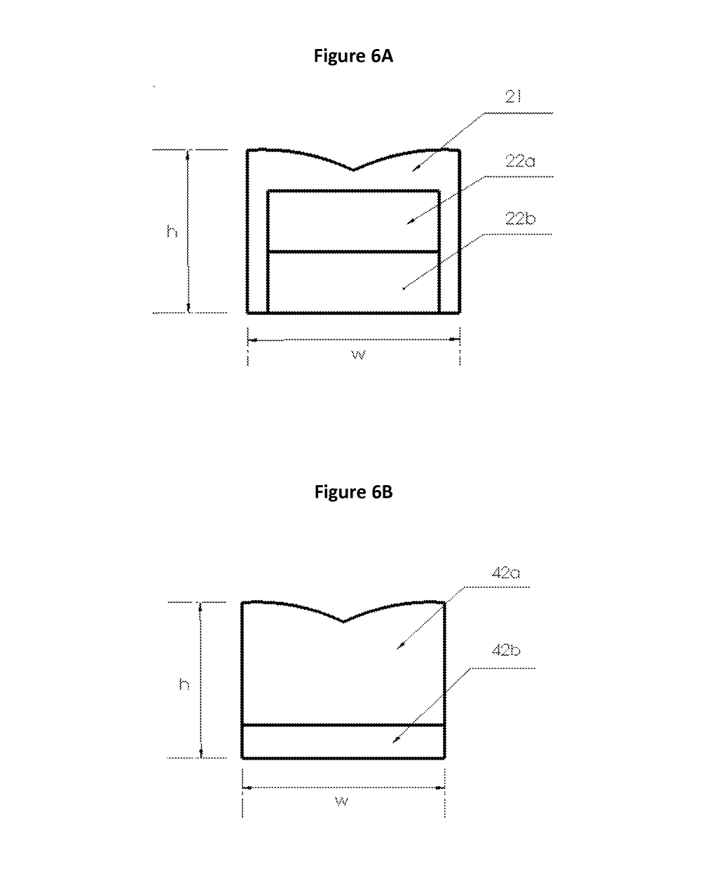

In some embodiments, a PCED structure 10 can comprise of two different layers of transparent materials containing different wavelength conversion materials such as green, yellow, orange, and/or red phosphor materials, and resides on top of the encapsulation layer 16 that can be made of a transparent material. One layer, the first layer, contains green and/or yellow phosphor materials and the second layer contains orange and/or red phosphor materials. In some embodiments, the first layer resides on top of the second layer. In some embodiments, the second layer resides on top of the first layer. In some embodiments, the PCED structure also comprises a clear structure forming outer surfaces of the PCED structure. FIGS. 6A-6B illustrate PCED structures with multiple layers and multiple phosphor containing layers. As illustrated in FIG. 6A, the PCED structure comprising a clear cladding layer 21 and two phosphor containing layers 22a and 22b. In one embodiment, the layer 22a contains green and/or yellow phosphor materials and the layer 22b contains orange and/or red phosphor materials. In another embodiment, the layer 22a contains orange and/or red phosphor materials and the layer 22b contains green and/or yellow phosphor materials. In FIG. 6B, there are two layers/structures 42a and 42b. In one embodiment, the layers/structures 42a and 42b are the first layer/structure and the second layer/structure, respectively, described in this paragraph. In another embodiment, the layers/structures 42a and 42b are the second layer/structure and the first layer/structure, respectively, described in this paragraph.

In certain embodiments, a PCED structure 10 can be formed directly on a light emitting package/unit by using molding techniques. In some embodiments, the PCED structure 10 is a premade unit that is attached on a light emitting unit by one of attachment techniques.

The PCED structure 10 can comprise a body defined by a bottom, a top, and a side. For example, one or more top surfaces, side surfaces, and/or bottom surfaces of the PCED structure 10 or portions thereof can be made of transparent materials. In some embodiments, the PCED body can be configured to receive light beams from the LED encapsulation 16 from the bottom and direct such light to the top. In certain embodiments, the top of the PCED 10 or a portion thereof comprises a total reflection surface configured to totally reflect at least part of incident light beams within the PCED structure 10 and redirect the totally reflected light beams toward the side. As a result, in certain embodiments, emitted light is not only emitted from the top surface of the optical structure but also from the side surfaces, resulting in more side light emission. In certain embodiments, the top and sides of the PCED 10 can be configured to direct totally or partially reflected light at the sides surface to within an extraction zone of incident solid angle at the top surfaces so that the reflected light can refract at the top surfaces. In certain embodiments, the top and sides of the PCED 10 can be configured to direct totally or partially reflected light at the top surface to within an extraction zone of incident solid angle at the side surfaces so that the reflected light can refract at the side surfaces.

### PCED Structure—Outer Structural Overview

As described above, in some embodiments, a light emitting device comprises a PCED structure 10. The PCED structure 10 can be configured to enhance light output and distribution of a light emitting device.

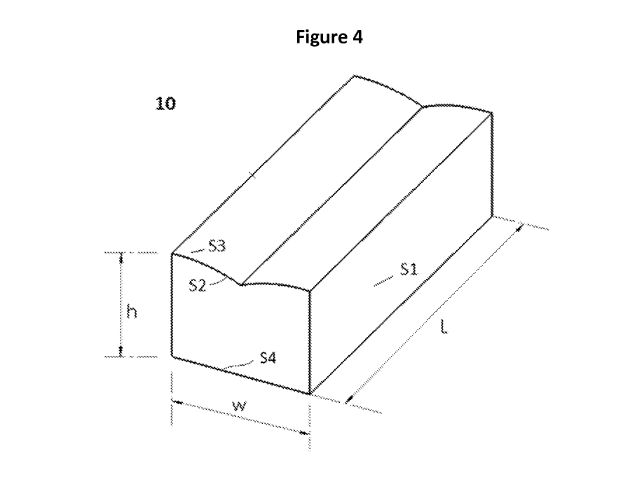

FIG. 4 illustrates a perspective view of an example of an embodiment of a PCED structure 10. As illustrated, some embodiments of a PCED structure 10 comprise one or more top, bottom, and/or side portions. The top, bottom, and/or side portions can further comprise one or more surfaces in certain embodiments. In some embodiments, the one or more top and/or side portions or surfaces thereof can be segmented unlike those of a hemispherical cover that comprises a single, continuous top and side portion.

In some embodiments, the light emitting device comprises a PCED structure 10 can be configured to be placed over a light source and/or LED encapsulation 16. Light emitted from the light source and/or LED encapsulation 16 can be configured to travel through the bottom portion of the PCED structure 10 and through the top and/or side portions thereof.

In some embodiments, a top portion of a PCED structure 10 comprises one or more top surfaces S2, S3. The one or more top surfaces S2, S3 can be parallel, angled, and/or curved with respect to an imaginary plane generally parallel to the bottom of the PCED structure 10. For example, in some embodiments, the one or more top surfaces S2, S3 can be angled such that a point along a top surface S2, S3 that is further from the center of the PCED structure 10 is at a higher level than a point along the same top surface S2, S3 that is closer to a center line along the top side of the PCED structure 10. In some embodiments, the top surfaces S2 comprise a concave-like shape or groove, as shown in FIG. 4, when viewing from outside the PCED structure 10.

In some embodiments, the one or more top surfaces S2, S3 can be segmented from each other. In certain embodiments, one of the plurality of top surfaces S2, S3 can form one or more angles with one or more other top surfaces S2, S3. For example, an angle formed between a top surface S3, S2 and one or more other top surfaces S2, S3 at any given point can be about 10°, about 20°, about 30°, about 40°, about 50°, about 60°, about 70°, about 80°, about 90°, about 100°, about 110°, about 120°, about 130°, about 140°, about 150°, about 160°, about 170°, or can vary within a range defined by two or more of the aforementioned angles. In other embodiments, a top surface S2, S3 is not segmented from one or more other top surfaces. Rather, a top surface S2, S3 can form a continuous surface with one or more other top surfaces S2, S3.

In some embodiments, one or more top surfaces S2, S3 or portions thereof can comprise an angle with respect to an imaginary plane parallel to the bottom surface S4. For example, the angle between the one or more top surfaces S2, S3 or portions thereof and the imaginary plane parallel to the bottom surface S4 at any given point can be about 0°, about 10°, about 20°, about 30°, about 40°, about 50°, about 55°, about 60°, about 70°, about 80°, about 90°, about 100°, about 110°, about 120°, about 130°, about 140°, about 150°, about 160°, about 170°, about 180°, or within a range defined by two or more of the aforementioned angles. In some embodiments, the angle between one or more top surfaces S2, S3 and the imaginary plane parallel to the one or more bottom surfaces S4 ranges from about 0° to about 45°.

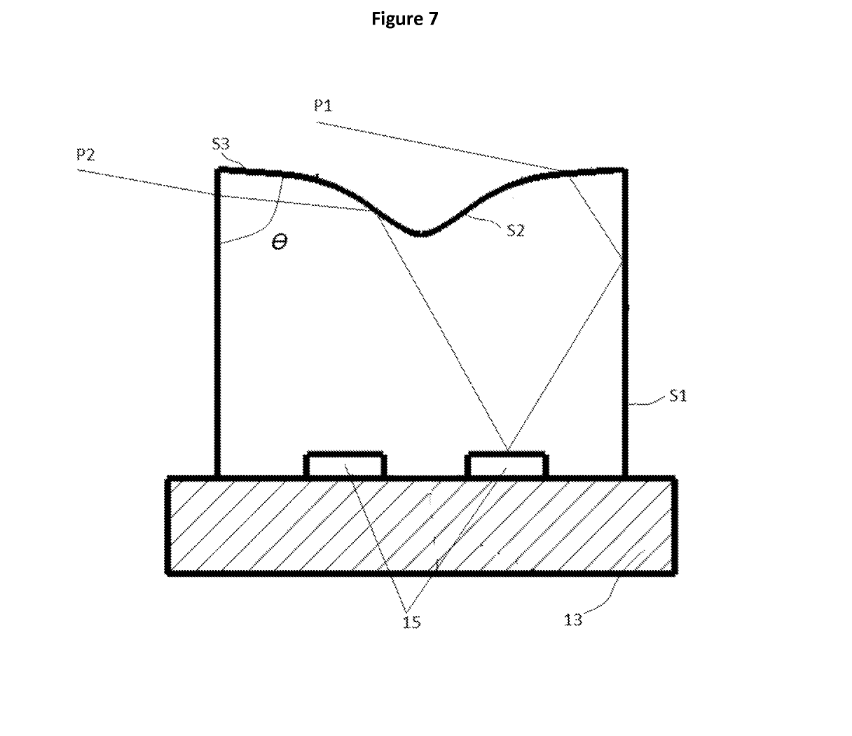

As illustrated in FIG. 7, some embodiments of a PCED structure 10 comprise one or more flat top surfaces S3. The one or more flat top surfaces S3 can be substantially parallel to a bottom surface S4 of the PCED structure 10.

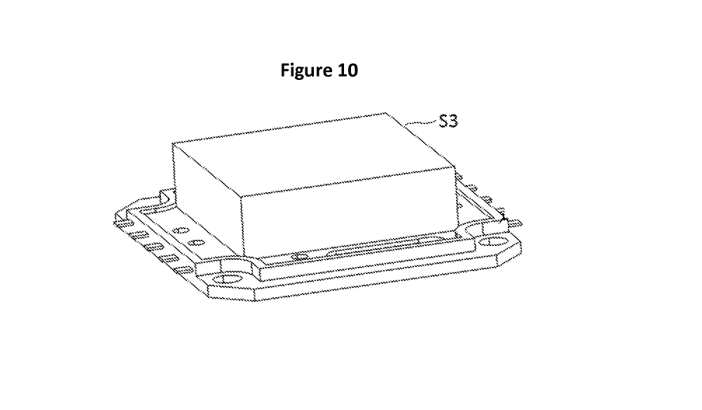

In some embodiments of a PCED structure 10 comprise one or more flat top surfaces S3 and there is no curved surfaces S2. The one or more flat top surfaces S3 can be substantially parallel to a bottom surface S4 of the PCED structure 10, as shown in FIG. 10.

In some embodiments, a side portion of a PCED structure 10 comprises one or more side surfaces S1. The one or more side surfaces S1 can be segmented from each other. In certain embodiments, one of the plurality of side surfaces S1 can form one or more angles with one or more other side surfaces S1. For example, an angle formed between a side surface S1 and one or more other side surfaces S1 at any given point can be about 10°, about 20°, about 30°, about 40°, about 50°, about 60°, about 70°, about 80°, about 90°, about 100°, about 110°, about 120°, about 130°, about 140°, about 150°, about 160°, about 170°, or can vary within a range defined by two or more of the aforementioned angles. In other embodiments, a side surface S1 is not segmented from one or more other side surfaces S1. Rather, a side surface S1 can form a continuous surface with one or more other side surfaces S1. In some embodiments, the one or more side surfaces S1 can form one or more angles with the bottom surface S4 and one or more angles with a top surface S2. For example, an angle form between a side surface S1 and the bottom surface S4 can be from 45° to 135°. For example, an angle form between a side surface S1 and a top surface S2/S3 can be from 45° to 135°.

### Light Guiding and Extraction

In some embodiments, by placing a PCED structure 10 over a light source and/or LED encapsulation 16, light that is emitted from the light source and/or LED encapsulation 16 can be configured to reflect and/or refract at particular angles as the light travels through and/or out of the PCED structure 10. FIG. 7 illustrates light travel patterns in examples of embodiments of PCED structures 10.

As illustrated, in some embodiments, a light emitting device can comprise a plurality of light sources 15 covered by a photon enhancement guiding structure 10. For example, a light source 15 can be located substantially underneath the PCED structure 10.

In some embodiments, one or more surfaces S1, S2, S3 can be made of transparent material such that light can be emitted and/or transmitted through the one or more surfaces S1, S2, S3. In certain embodiments, light emitted from one or more light sources 15 or phosphor materials can be refracted by an angle at the surfaces S1, S2, S3. The angle of refraction can depend on the refractive index of the material of that particular surface S1, S2, S3 and the incident angle between the path of incident light before contacting the surface S1, S2, S3 and a line/plane tangential to the point of contact along the surface S1, S2, S3.

In certain embodiments, one or more surfaces S2, S3 can be configured in relation to the side surfaces S1 in a manner that some reflected light undergoing total internal reflection mechanism at the surfaces S2, S3 can be transmitted through the surfaces Si, or in a manner that reflected light undergoing total internal reflection mechanism at the surfaces S1 can be transmitted through the surfaces S2, S3. With this guiding phenomenon, which can be denoted as “reflective refractive guiding”, the angle of emitted light can be controlled through the angle relation between the surfaces S2, S3 and the surfaces S1. For example, as illustrated in FIG. 7, light P1 is reflected at a surface S1 to a surface S2/S3 where it is refracted. The angle of transmitted light P1 depends on the configuration of between the surfaces S2, S3 and the surfaces Si.

In certain embodiments, one or more surfaces S2 can be configured to direct light to the side surfaces S1 at which the directed light is transmitted through. For example, as illustrated in FIG. 7, light P2 is reflected at a surface S2 to a surface S1 where it is refracted. The angle of transmitted light P1 depends on the configuration of between the surfaces S2 and the surfaces S1.

In certain embodiments, the height h can be as high as possible and the width w is as small as possible to improve light extraction efficiency of the PCED structure 10. The height h can be limited by the transparent level of transparent materials that are used to make the PCED structure. For example, the height h can be about 0.1 mm to 5 mm, about 5 mm to 10 mm, about 10 mm to 15 mm. The ratio of the height h to the width w can be from 0.2 mm to 1.5 mm, but not limited to upper limit. The height h of PCED structure can be minimized to reduce the absorption loss, bulkiness, and material cost by reducing the width w of a PCED structure.

### PCED Structure —Conical or Polygonal Structures

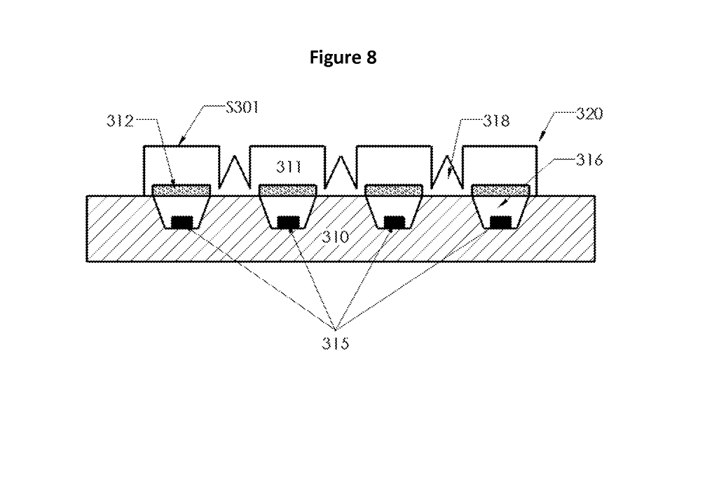

In some embodiments, the top portion of a PCED structure 10 can comprise a plurality of at least one type of sub-structures. In some embodiments, the top portion of a PCED structure 10 can comprise a plurality of at least two types of sub-structures. The sub-structures can be one of truncated-pyramidal, -polygonal, -conical, pyramidal, polygonal, conical, cylindrical, curved structures. In some embodiments, the sub-structures can be arranged in any orders. In some embodiments, the sub-structures of different types can be arranged in alternative positions. For example, FIG. 8 shows a PCED structure 320 with a conical/pyramidal structure 318 between two adjacent polygonal/cubical structures 311 having a top surface S301. With this arrange, the top portion of a PCED structure can be divided into multiple small sub-structures along the length L. Therefore, the effective length for light extraction and distribution can be as small as or smaller than the width w. This means the effective ratio of the height h to the effective length L can be larger than the ratio of the height h to the length L.

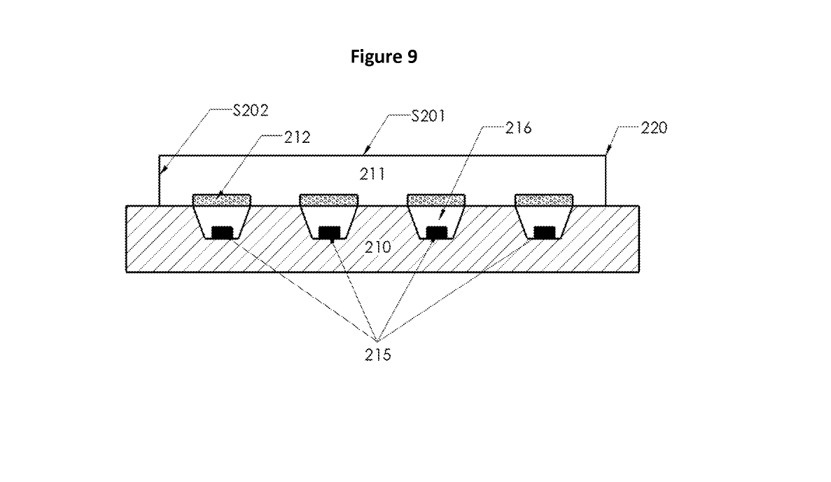

In some embodiments, as illustrated in FIGS. 8 and 9, a PCED structure 320 or 220 can comprise plurality of segments 312 or 212 containing phosphor materials and covering each cavity of the substrate housing 310 or 210 in which at least one LED chip 315 or 215 resides, and a transparent structure that forms outer surfaces of the PCED structure. The phosphor segments 312 reside on top of the encapsulation layer 316 or 216.

In some embodiments, as illustrated in FIG. 10, a PCED structure has a flat top surface S3.

What is claimed is:

1. A light emitting device:
an LED light source comprising at least one light emitting diode (LED) and an encapsulation encapsulating the LED, the LED being configured to emit light beams of a first color;
phosphor materials that absorb the first color from the LED and emit light beams of at least another color and that are blended in transparent materials to form a wavelength conversion layer; and
a photon conversion, extraction, and distribution (PCED) structure placed over the LED encapsulation, the PCED structure comprising a body defined by a bottom, a top and a side, the PCED structure body being configured to receive via the bottom and direct to the top light beams from the LED encapsulation.

2. The device of claim 1, wherein the top of the PCED structure is flat that forms an angle with the side.

3. The device of claim 2, wherein the angle between the top and side of the PCED structure is configured so that light undergoing total internal reflection at the side can be transmitted at the top and light undergoing total internal reflection at the top can be transmitted at the side, wherein this angle range is determined by the refractive indices of the material of the PCED structure and the environment (air).

4. The device of claim 1, wherein the top of the PCED structure comprises a dip or groove or curve at around a center line along an axis of the PCED structure to direct some of the first color to the side.

5. The device of claim 1, wherein the PCED structure preferably has the ratio of its height to its width being from 0.2 to 1.5, but not limit to the upper limit.

6. The device of claim 1, wherein the top and side of the PCED structure have most of their tangential planes at each point on the top and the side forming an angle between 45 to 135 degrees, wherein this angle range depends on refractive index of the material of PCED structure and the position of each point.

7. The device of claim 6, wherein the angle is configured to allow reflection-refraction mechanism, meaning reflected light one surface is refracted at its coupled surface.

8. The device of claim 1, wherein the top of the PCED structure comprises a continuous surface along the length of the PCED structure.

9. The device of claim 1, wherein the top of the PCED structure comprises a plurality of at least two types of sub-structures such as truncated-pyramidal, -polygonal, -conical, pyramidal, polygonal, conical, cylindrical, curved structures, wherein these substructures can improve the effective ratio of its height to its width.

10. The device of claim 9, wherein sub-structures can be arranged in any orders.

11. The device of claim 9, wherein sub-structures of one type can be arranged between substructures of another type.

12. The device of claim 1, wherein the encapsulation contains phosphor materials and the PCED structure is made of a transparent material.

13. The device of claim 1, wherein the encapsulation is made of a transparent material and the PCED structure is made of a transparent material containing phosphor materials.

14. The device of claim 13, wherein the PCED structure has a phosphor layer or multiple segments of a phosphor layer residing below and/or inside a clear structure.

15. The device of claim 13, wherein the PCED structure has at least two phosphor layers residing below and/or inside a clear structure, wherein each layer contains different phosphor materials emitting different color.

16. The device of claim 1, wherein the encapsulation comprises different layers, wherein a layer containing red and/or orange phosphor materials resides on top of a layer containing green and/or yellow phosphor materials.

17. The device of claim 1, wherein the PCED structure has one of polygonal, circular, elliptical bases, wherein the base shape is similar to the bottom view of the PCED structure.

18. The device of claim 1, wherein the LED can emit a third color such at orange and/or red.

19. A method of improving light efficiency of an LED package and directing light beams for better color mixing and spreading, the method comprising:
providing the device of claim 1;
emitting light beams from the LED light source toward the PCED structure so that a light beam enters the PCED body and travels toward emitting surfaces; and
directing a light beam undergoing total internal reflection or Fresnel reflection at one of outer surfaces toward another outer surface and to critical angle zone (extraction zone of solid angle) so that reflection-refraction mechanism is enabled, wherein the reflection-refraction mechanism is assisted by the configuration of pairs of a side surface and a top surface.
